(19) United States
(12) Patent Application Publication
(10) Pub. No.: US 2024/0055441 A1
(43) Pub. Date: Feb. 15, 2024

(54) WAFER SIGNAL AND POWER ARRANGEMENT FOR NANOSHEET DEVICES

(71) Applicant: International Business Machines Corporation, Armonk, NY (US)

(72) Inventors: Tao Li, Slingerlands, NY (US); Ruilong Xie, Niskayuna, NY (US); Chih-Chao Yang, Glenmont, NY (US); Lawrence A. Clevenger, Saratoga Springs, NY (US)

(21) Appl. No.: 17/819,710

(22) Filed: Aug. 15, 2022

(51) Int. Cl. H01L 27/12

(52) U.S. Cl. CPC H01L 27/124; H01L 27/1266; H01L 27/1222

(57) ABSTRACT

A semiconductor device includes an integrated circuit chip having a frontside and a backside. The frontside includes a frontside signal line configured to transmit signals to a first terminal of a transistor arranged in the integrated circuit chip, and the backside includes a backside power line configured to transmit power to a second terminal of the transistor. The semiconductor device further includes a contact configured to connect a gate of the transistor to a backside signal line configured to transmit signals to the gate of the transistor. The semiconductor device further includes a via extending through the frontside and the backside of the integrated circuit chip. The via is configured to transmit signals between a lowermost contact on the frontside and an uppermost contact on the backside of the integrated circuit chip.

### BACKGROUND

The present disclosure relates to the semiconductor device fields. In particular, the present disclosure relates to arrangement and manufacture of signal lines and power lines on a semiconductor device.

The complexity of an integrated circuit is bounded by physical limitations, such as the number of transistors that can be put onto one chip, the number of package terminations that can connect the processor to other parts of the system, the number of interconnections it is possible to make on the chip, and the heat that the chip can dissipate. As integrated circuit technology has advanced, it has become feasible to manufacture more and more complex processors on a single chip. Limitations remain, however, regarding the number of package terminations that can connect the processor to other parts of the system and the space available for wiring.

### SUMMARY

Embodiments of the present disclosure include a semiconductor device. The semiconductor device includes an integrated circuit chip having a frontside and a backside. The frontside includes a frontside signal line configured to transmit signals to a first terminal of a transistor arranged in the integrated circuit chip. The backside includes a backside power line configured to transmit power to a second terminal of the transistor. The semiconductor device further includes a contact configured to connect a gate of the transistor to a backside signal line. The backside signal line is configured to transmit signals to the gate of the transistor. The semiconductor device further includes a via extending through the frontside and the backside of the integrated circuit chip. The via is configured to transmit signals between a lowermost contact on the frontside of the integrated circuit chip and an uppermost contact on the backside of the integrated circuit chip.

Additional embodiments of the present disclosure include a semiconductor device. The semiconductor device includes an integrated circuit chip having a frontside and a backside. The integrated circuit chip includes a first FET arranged in a first FET region and a second FET arranged in a second FET region. The first FET region and the second FET region are separated from one another by a space. The semiconductor device further includes first contact connecting a backside power line to a terminal of the first FET. The backside power line is arranged on the backside of the integrated circuit chip. The semiconductor device further includes a second contact connecting a frontside signal line to a terminal of the second FET. The frontside signal line arranged on the frontside of the integrated circuit chip. The semiconductor device further includes a third contact connecting a backside signal line to a gate that connects the first FET and the second FET. The backside signal line arranged on the backside of the integrated circuit chip. The first contact includes a first portion having a first centerline which is aligned with a centerline of the terminal of the first FET, and the first contact includes a second portion having a second centerline which is not aligned with the centerline of the terminal of the first FET

Additional embodiments of the present disclosure include a method of making a semiconductor device. The method includes forming a frontside device on a wafer such that the frontside device including a first FET in a first FET region, a second FET in a second FET region, a placeholder that is in direct contact with a terminal of the first FET, and a frontside contact connected to a frontside signal line. The method further includes removing the wafer substrate from the frontside device. The method further includes creating an opening that removes a portion of the placeholder, the opening having a centerline that is offset relative to a centerline of a terminal of the first FET. The method further includes removing a remainder of the placeholder to expose the terminal of the first FET. The method further includes forming a backside device including filling the opening with contact material to form a first backside contact that is in direct contact with the terminal of the first FET, the backside device including a backside power line connected to the first backside contact and a backside signal line connected to a second backside contact such that the backside signal line is arranged between the first FET region and the second FET region.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

FIG. 1 illustrates a flowchart of an example method for forming a nanosheet device, in accordance with embodiments of the present disclosure.

FIG. 2 depicts a schematic diagram illustrating a top plan view of an example device formed by performing a portion of the method 100, in accordance with embodiments of the present disclosure.

FIGS. 3A-3C illustrate cross-sectional schematic views of an example of a structure following the performance of a portion of the example method of FIG. 1, in accordance with embodiments of the present disclosure.

FIGS. 4A-4C illustrate cross-sectional schematic views of an example of a structure following the performance of a portion of the example method of FIG. 1, in accordance with embodiments of the present disclosure.

FIGS. 5A-5C illustrate cross-sectional schematic views of an example of a structure following the performance of a portion of the example method of FIG. 1, in accordance with embodiments of the present disclosure.

FIGS. 6A-6C illustrate cross-sectional schematic views of an example of a structure following the performance of a portion of the example method of FIG. 1, in accordance with embodiments of the present disclosure.

FIGS. 7A-7C illustrate cross-sectional schematic views of an example of a structure following the performance of a portion of the example method of FIG. 1, in accordance with embodiments of the present disclosure.

FIGS. 8A-8C illustrate cross-sectional schematic views of an example of a structure following the performance of a portion of the example method of FIG. 1, in accordance with embodiments of the present disclosure.

FIGS. 9A-9C illustrate cross-sectional schematic views of an example of a structure following the performance of a portion of the example method of FIG. 1, in accordance with embodiments of the present disclosure.

FIGS. 10A-10C illustrate cross-sectional schematic views of an example of a structure following the performance of a portion of the example method of FIG. 1, in accordance with embodiments of the present disclosure.

FIGS. 11A-11C illustrate cross-sectional schematic views of an example of a structure following the performance of a portion of the example method of FIG. 1, in accordance with embodiments of the present disclosure.

FIGS. 12A-12C illustrate cross-sectional schematic views of an example of a structure following the performance of a portion of the example method of FIG. 1, in accordance with embodiments of the present disclosure.

FIGS. 13A-13C illustrate cross-sectional schematic views of an example of a structure following the performance of a portion of the example method of FIG. 1, in accordance with embodiments of the present disclosure.

FIGS. 14A-14C illustrate cross-sectional schematic views of an example of a structure following the performance of a portion of the example method of FIG. 1, in accordance with embodiments of the present disclosure.

FIG. 15 illustrates a cross-sectional schematic view of an example of a structure following the performance of a portion of the example method of FIG. 1, in accordance with embodiments of the present disclosure.

### DETAILED DESCRIPTION

The present disclosure relates to the semiconductor device fields. In particular, the present disclosure relates to arrangement and manufacture of signal lines and power lines on a semiconductor device. While the present disclosure is not necessarily limited to such applications, various aspects of the disclosure may be appreciated through a discussion of various examples using this context.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching is any process that removes material from the wafer. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping is the modification of electrical properties by selectively adding impurities, for example, transistor sources and drains, generally by diffusion and/or by ion implantation. These doping processes may be followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

Turning now to an overview of technologies that are more specifically relevant to aspects of the present disclosure, in general, in electronics, a wafer is a thin slice of semiconductor, such as a crystalline silicon, used for the fabrication of integrated circuits. The wafer serves as the substrate for microelectronic devices built in and upon the wafer. Ultimately, individual microcircuits are separated by wafer dicing and packaged as an integrated circuit.

One example of a microelectronic device built in and upon wafers is a field-effect transistor (FET). A FET uses an electric field to control the flow of current in a semiconductor. More specifically, FETs control the flow of current by the application of a voltage to the gate, which in turn alters the conductivity between the drain and source. A FET uses either electrons (in an n-channel FET, also referred to as an nFET) or holes (in a p-channel FET, also referred to as a pFET) for conduction. The four terminals of the FET are typically referred to as the source, gate, drain, and body, which may also be referred to as the substrate. In a FET, the drain-to-source current flows via a conducting channel that connects the source region to the drain region. The conductivity is varied by the electric field that is produced when a voltage is applied between the gate and source terminals. Accordingly, the current flowing between the drain and source is controlled by the voltage applied between the gate and source.

The complexity of an integrated circuit is bounded by physical limitations such as the number of transistors that can be put onto one chip, the number of package terminations that can connect the processor to other parts of the system, the number of interconnections it is possible to make on the chip, and the heat that the chip can dissipate. As integrated circuit technology has advanced, it has become feasible to manufacture more and more complex processors on a single chip. Limitations remain, however, regarding the number of package terminations that can connect the processor to other parts of the system and the space available for wiring. One strategy for improving the efficiency of the utilization of available space for wiring is to utilize both sides (the frontside and the backside) of the wafer for power and signal delivery.

More specifically, as described in further detail below, embodiments of the present disclosure provide a structure and a method for forming a semiconductor device having an arrangement of signal and power lines such that the frontside of the wafer includes signal delivery lines and the backside of the wafer includes both power and signal delivery lines. As explained in further detail below, the arrangement is suitable for nanosheet devices with direct backside source/drain (S/D) contact. Additionally, as further described below, the arrangement is suitable for nanosheet devices having gate contact at an aggressive pitch.

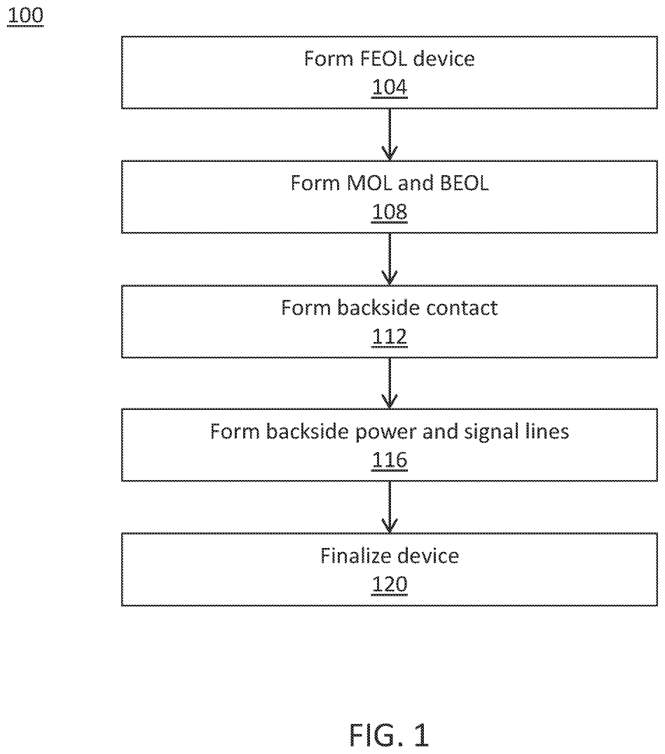

FIG. 1 depicts a flowchart of an example method 100 for forming a semiconductor device having an arrangement of signal and power lines such that the frontside of the wafer includes signal delivery lines and the backside of the wafer includes both power and signal delivery lines, according to embodiments of the present disclosure. The method 100 begins with operation 104, wherein a front end of line (FEOL) device is formed. In particular, operation 104 includes forming a FEOL device with a dummy placeholder under the S/D epitaxy material that makes up terminals of FETs of the device and a gate metal extension into shallow trench isolation (STI). In accordance with some embodiments of the present disclosure, the performance of operation 104 further includes the performance of a number of sub-operations.

In accordance with at least one embodiment of the present disclosure, the performance of operation 104 includes forming a FEOL device on a frontside of a wafer. The FEOL device is formed such that dummy placeholders are formed under the S/D epitaxy material. As described in further detail below, some of the dummy placeholders are later removed and replaced with backside contacts. The FEOL device is further formed such that a gate metal extension is formed in the STI. As described in further detail below, the gate metal extension will later enable backside signal delivery

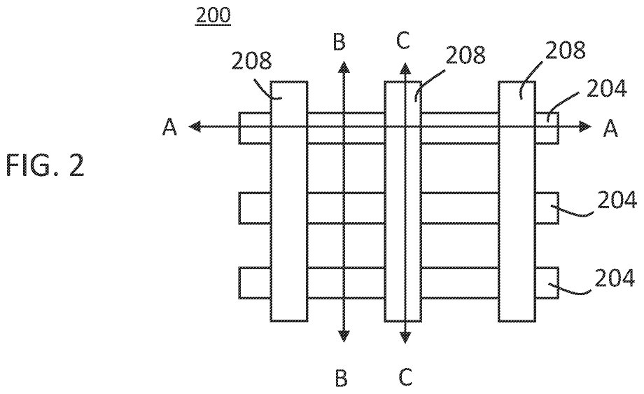

FIG. 2 depicts a schematic diagram illustrating a top plan view of an example device 200 formed in accordance with embodiments of the method 100. The diagram is used to indicate where cuts are made along the device to provide the cross-sectional views that illustrate various features of the device. In particular, the line labeled A-A in FIG. 2 indicates a cut that is made along a length of the nanosheet fin 204, and therefore provides a cross-sectional view that shows each of the gates 208 formed thereon. The line labeled B-B indicates a cut that is made perpendicular to the A-A cut and is cut between two gates 208. The line labeled C-C indicates a cut that is made parallel to the B-B cut and is cut into one of the gates 208.

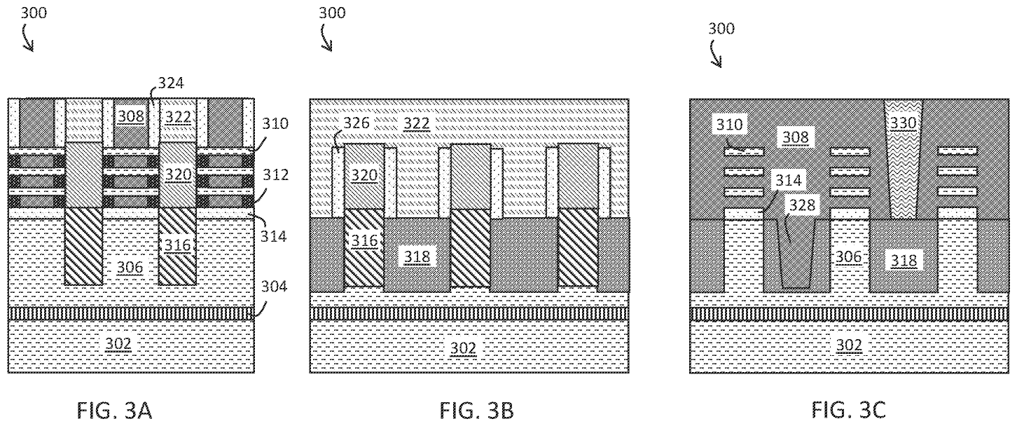

FIGS. 3A-3C depict an example structure 300 following the performance of the portion of operation 104 described above. FIG. 3A illustrates a cross-sectional view of the example structure 300 cut along the A-A cut shown in FIG. 2. FIG. 3B illustrates a cross-sectional view of the example structure 300 cut along the B-B cut shown in FIG. 2. FIG. 3C illustrates a cross-sectional view the example structure 300 cut along the C-C cut shown in FIG. 2. This arrangement of the views made along each of these cuts is maintained from FIGS. 3A-3C through FIGS. 14A-14C.

The example structure 300 shown in FIGS. 3A-3C includes a substrate 302 and an etch stop layer 304 formed above the substrate 302. The substrate 302 can be made of, for example, silicon. The example structure 300 further includes a further layer 306 of silicon formed on top of the etch stop layer 304. As shown in FIGS. 3A and 3C, the example structure 300 further includes high-k metal gate (HKMG) material forming the metal gates 308 of the structure 300. Silicon sheets 310 are arranged so as to extend through the metal gates 308 and are separated from one another by isolation layers 312. The isolation layers 312 can be made of, for example, silicon nitride. The isolation layers 312 and the metal gates 308 are separated from the further layer 306 of silicon by a bottom dielectric isolation layer (BDI) 314 (shown in FIGS. 3A and 3C).

As shown in FIGS. 3A and 3B, the example structure 300 further includes dummy placeholders 316 that extend into the further layer 306 of silicon in the nanosheet between each of the metal gates 308 (as shown in FIG. 3A) and extend into a layer of (STI) 318 that is arranged on top of the further layer 306 of silicon between each nanosheet (as shown in FIG. 3B). Each dummy placeholder 316 is arranged beneath a region of S/D epitaxy material 320 of a transistor. The example structure 300 is further filled with inner layer dielectric (ILD) 322. As shown in FIG. 3A, the HKMG material of the metal gates 308 is isolated from the ILD 322 by isolation regions 324. The isolation regions 324 can be made of, for example, the same material as the BDI 314. As shown in FIG. 3C, similar isolation regions 326 are arranged between the S/D epitaxy material 320 and the dummy placeholders 316 above the STI 318.

As shown in FIG. 3C, the gate along which the C-C cut is made in FIG. 2 includes a gate metal extension 328 made of the HKMG material that extends into the STI 318 as well as a gate cut 330 that extends through the HKMG material to the STI 318 at a location between sets of silicon sheets 310.

The features of the FEOL device described above and shown in FIGS. 3A-3C can be formed in the performance of operation 104 using conventional techniques. Accordingly, further description of their formation is not provided herein.

Returning to FIG. 1, following the performance of operation 104, the method 100 proceeds with operation 108, wherein middle of line (MOL) and back end of line (BEOL) features are formed. In accordance with some embodiments of the present disclosure, the performance of operation 108 further includes the performance of a number of sub-operations.

In accordance with at least one embodiment of the present disclosure, the performance of operation 108 includes forming MOL contacts and metallization. More specifically, the performance of operation 108 includes forming a further layer of ILD above the gates and forming patterned openings in the ILD and further layer of ILD. The performance of operation 108 further includes filling the patterned openings with a conductive material to form MOL contacts.

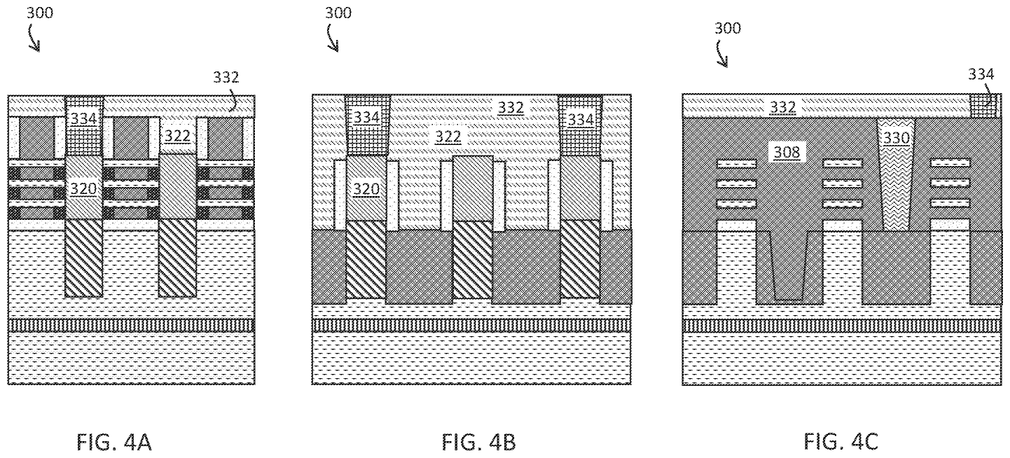

FIGS. 4A-4C show the structure 300 following the performance of this portion of operation 108. As shown, a further layer of ILD 332 has been formed above the gates. Accordingly, in FIGS. 4A and 4B, the further layer of ILD 332 is formed in direct contact with the existing ILD 322 as well as the gates 308 and the isolation regions 324. As shown in FIG. 4C, the further layer of ILD 332 covers the top of the gate 308 as well as the top of the gate cut 330.

As further shown in FIGS. 4A-4C, the patterned openings, which have been filled with conductive material 334, are formed such that the conductive material 334 is in direct contact with some of the S/D epitaxy material 320 (as shown in FIGS. 4A and 4B) and is in direct contact with a portion of the top of the gate 308 that is offset from the gate cut 330 (shown in FIG. 4C). The particular arrangement of the conductive material 334 shown in FIGS. 4A-4C is for illustrative purposes only. In alternative embodiments, the arrangement of the conductive material 334 can be different that that shown, depending on the particular applications and functions of the actual device.

In accordance with at least one embodiment of the present disclosure, the performance of operation 108 further includes forming BEOL features in contact with the MOL features. More specifically, the performance of operation 108 includes forming insulative layers above the further layer of ILD and forming patterned openings in the insulative layers. The performance of operation 108 further includes filling the patterned openings with a conductive material to form BEOL interconnects, in particular, vias and signal lines.

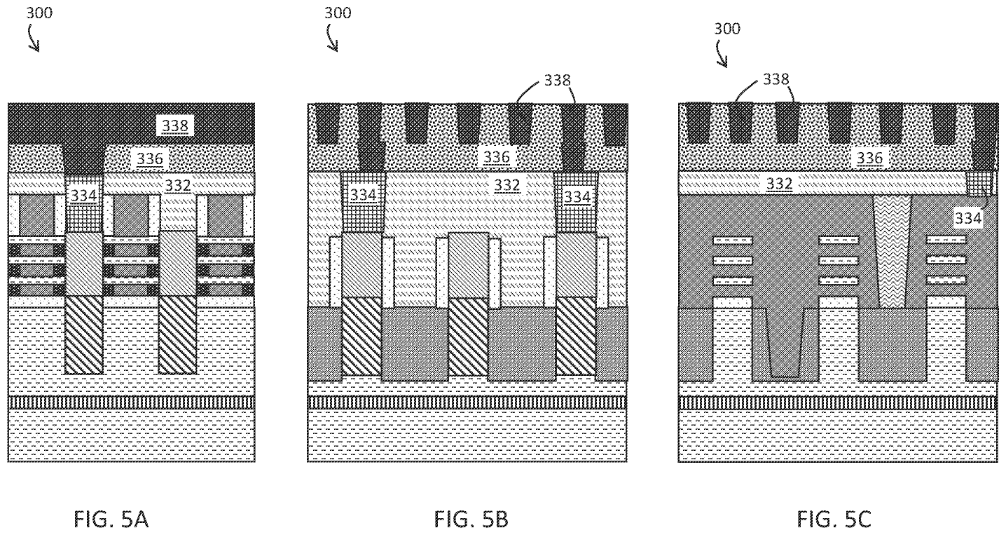

FIGS. 5A-5C depict the structure 300 following the performance of this portion of operation 108. As shown, the insulative layers 336 are formed on top of the further layer of ILD 332 and the contacts made of conductive material 334 formed therein. The insulative layers 336 are patterned and metallized to form BEOL interconnects 338 that interconnect the contacts made of conductive material 334. In particular, the BEOL interconnects 338 include vias and signal lines. Accordingly, following the performance of this portion of operation 108, the frontside of the device 300 includes a plurality of signal lines.

In accordance with at least one embodiment of the present disclosure, the performance of operation 108 further includes forming at least one further layer of BEOL interconnects and bonding a carrier wafer to the top of the uppermost layer of BEOL interconnects. Each further layer of BEOL interconnects is formed in substantially the same manner as described above. The number of further layers of BEOL interconnects that are formed are determined by the application and function of the particular device.

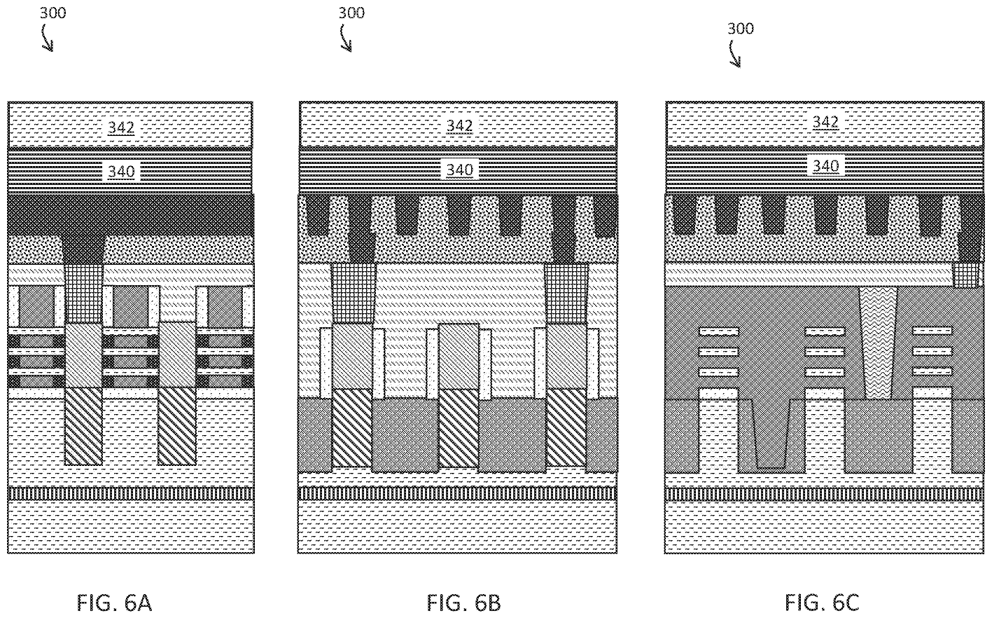

FIGS. 6A-6C depict the structure 300 following the performance of this portion of operation 108. For illustrative purposes, the further layer(s) of BEOL interconnects are represented in the figures simply as a single structure 340. As shown, the further layer(s) of BEOL interconnects 340 are bonded to, and therefore covered by, the carrier wafer 342. Accordingly, following the performance of this portion of operation 108, the frontside of the device has been completed and isolated.

In accordance with at least one embodiment of the present disclosure, the performance of operation 108 further includes performing a chip-flip. As is known in the art, a chip-flip is a 180 degree vertical inversion of the existing device. Accordingly, following a chip-flip, the substrate that previously formed the bottom of the device is now arranged on the top of the device such that the backside of the substrate wafer is exposed.

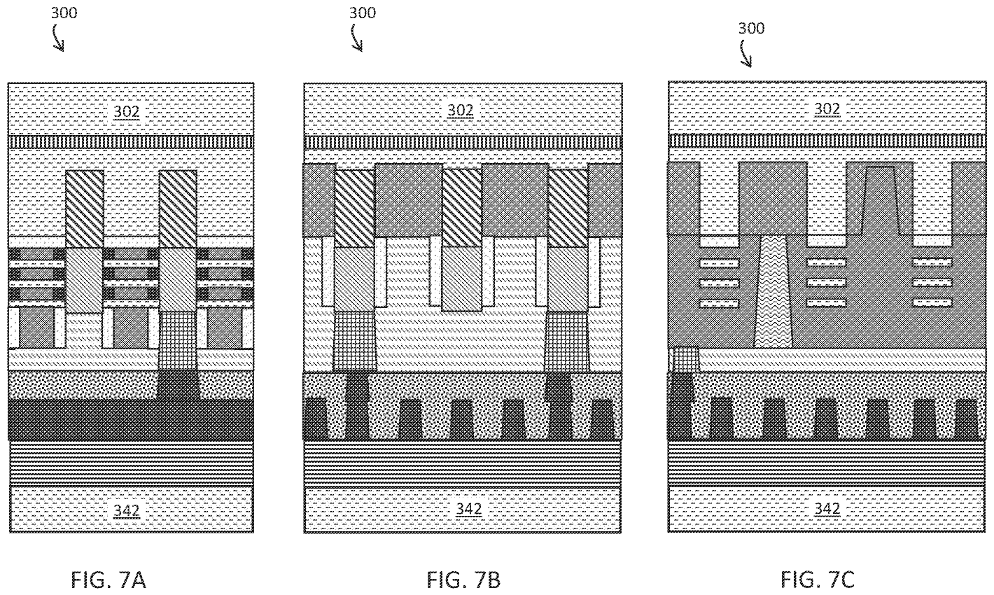

FIGS. 7A-7C depict the structure 300 following the performance of this portion of operation 108. As shown, the carrier wafer 342 is arranged at the bottom and the substrate 302 is arranged at the top such that the backside of the substrate 302 is exposed.

Returning to FIG. 1, following the performance of operation 108, the method 100 proceeds with operation 112, wherein backside contacts are formed on the device. In accordance with some embodiments of the present disclosure, the performance of operation 112 further includes the performance of a number of sub-operations.

In accordance with at least one embodiment of the present invention, the performance of operation 112 includes removing the substrate to the etch stop layer.

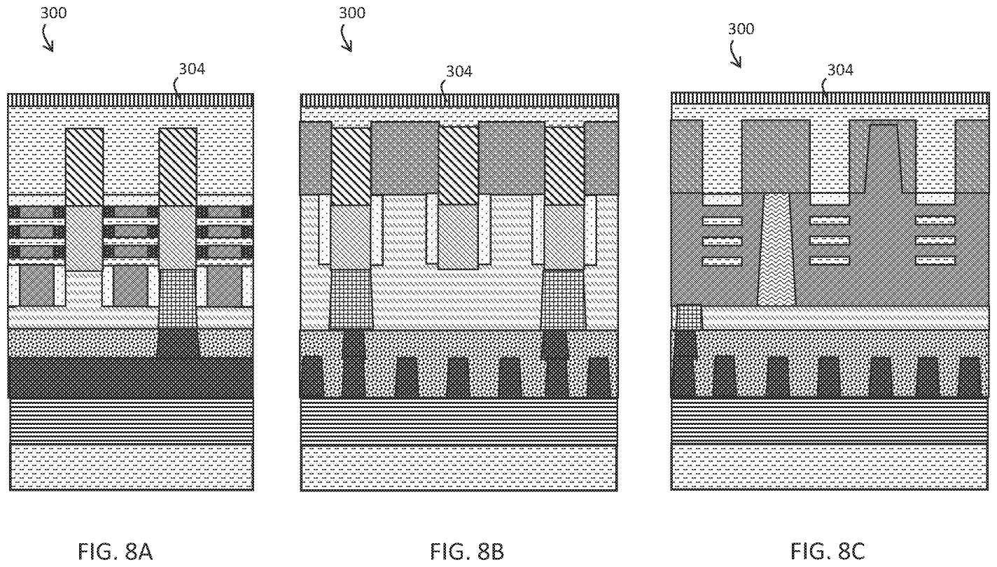

FIGS. 8A-8C depict the device 300 following the performance of this portion of operation 112. As shown, the substrate 302 (shown in FIGS. 7A-7C) has been removed down to the etch stop layer 304 such that the etch stop layer 304 is exposed by the removal of the substrate 302 and forms the uppermost surface of the device 300.

In accordance with at least one embodiment of the present invention, the performance of operation 112 further includes removing the etch stop layer.

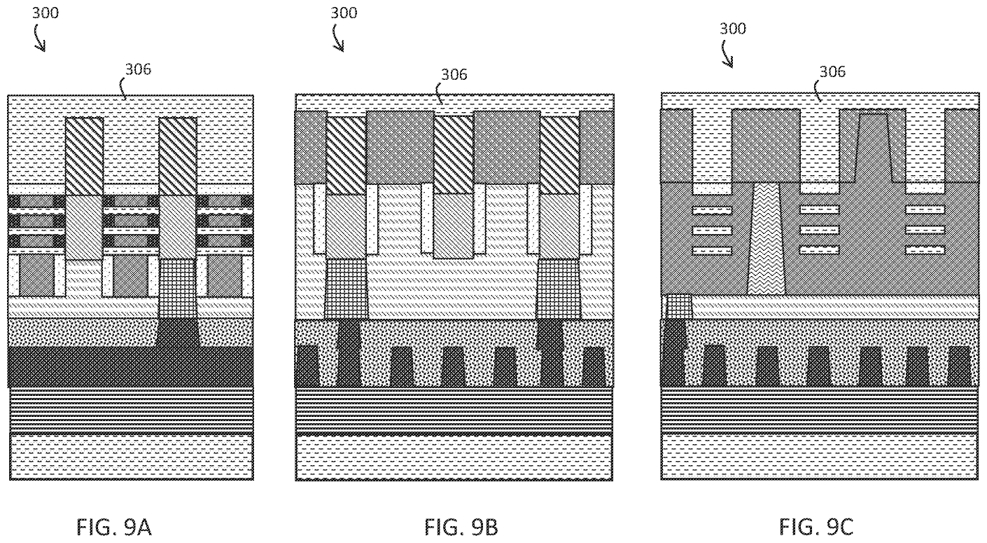

FIGS. 9A-9C depict the device 300 following the performance of this portion of operation 112. As shown, the etch stop layer 304 (shown in FIGS. 8A-8C) has been removed to expose the further layer 306 of silicon such that the further layer 306 of silicon is exposed by the removal of the etch stop layer 304 and forms the uppermost surface of the device 300.

In accordance with at least one embodiment of the present invention, the performance of operation 112 further includes removing the remaining silicon of the further layer of silicon and filling the space created by the removal of the remaining silicon with ILD. Because this ILD is formed on the backside of the device, it is also referred to herein as backside ILD (BILD). Following its formation, the BILD is planarized to ensure that the uppermost surface of the device is level. The BILD can be planarized, for example, by performing CMP.

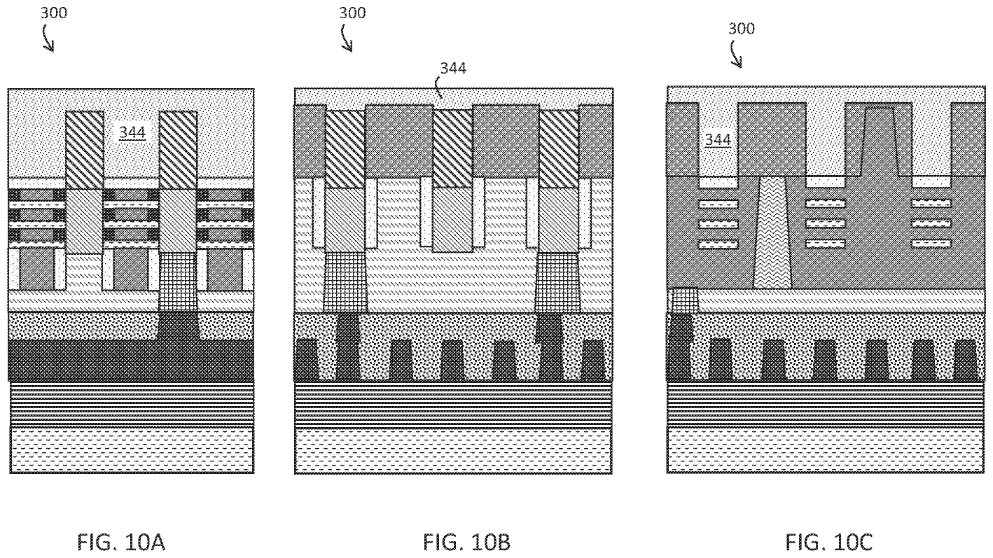

FIGS. 10A-10C depict the device 300 following the performance of this portion of operation 112. As shown, the remaining silicon of the further layer 306 of silicon has been removed and replaced with BILD 344, and the BILD 344 has been planarized such that the uppermost surface of the device 300 is level.

In accordance with at least one embodiment of the present invention, the performance of operation 112 further includes performing backside contact patterning. More specifically, the performance of operation 112 further includes forming openings in the BILD to be filled with conductive material. Notably, the openings are formed such that a portion of at least one of the dummy placeholders is exposed and also removed, thereby exposing the at least one dummy placeholder. Additionally, the openings are also formed such that a portion of the STI surrounding the gate metal extension is also removed, thereby exposing a portion of the gate metal extension.

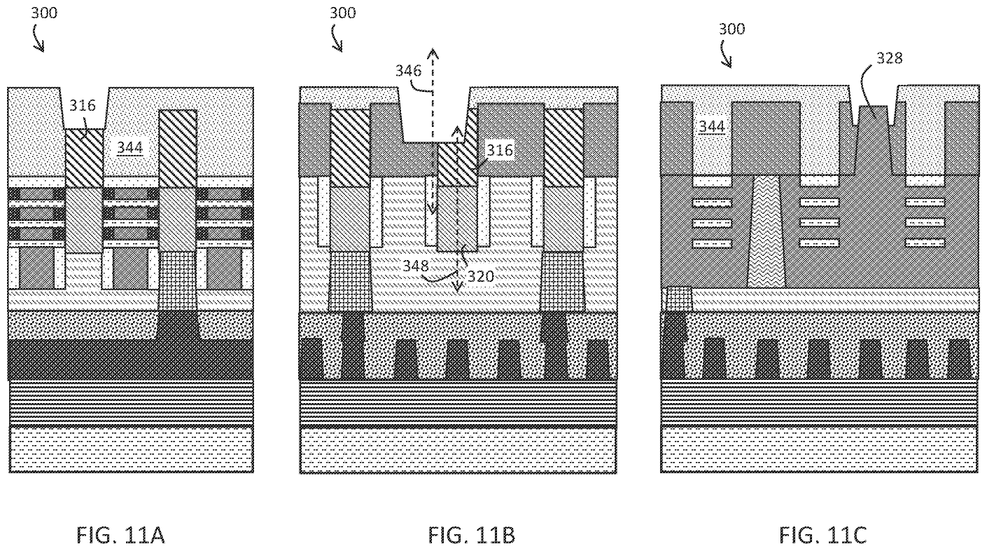

FIGS. 11A-11C depict the device 300 following the performance of this portion of operation 112. As shown, portions of the BILD 344, dummy placeholders 316, and STI 318 are selectively patterned and removed. Accordingly, those dummy placeholders 316 which were partially removed are now exposed. Additionally, a portion of the gate metal extension 328 is also exposed.

Notably, as shown in FIG. 11B, the backside contact patterning is performed such that the opening formed in the area of the device between two gates 208 (shown in FIG. 2) is offset relative to the dummy placeholder 316 which it partially removed. In other words, the centerline 346 of the opening is not aligned with the centerline 348 of the S/D epitaxy material 320 arranged beneath the dummy placeholder 316 which has been partially removed. The centerlines 346, 348 are defined by the view of the device 300 cut along the line B-B in FIG. 2. Accordingly, it is in this plane that the centerline 346 is not aligned with the centerline 348. Instead, as shown in FIG. 11B, the centerline 346 is approximately parallel to the centerline 348. In alternative embodiments, the centerline 346 need not be approximately parallel to the centerline 348 but is still offset relative to the centerline 348 such that the centerlines 346, 348 are not co-incident with one another. In other words, in all embodiments, the centerline 346 is independent and distinct from the centerline 348, and the two cannot be defined as the same line.

As described in further detail below, the offset of the opening relative to the S/D epitaxy material enables the subsequent formation of backside power and signal lines with adequate spacing therebetween. Accordingly, this offset enables an arrangement of both power and signal delivery lines on the backside of the wafer that is suitable for nanosheet devices with direct backside source/drain (S/D) contact and is suitable for nanosheet devices having gate contact at an aggressive pitch.

In accordance with at least one embodiment of the present invention, the performance of operation 112 further includes the selective removal of the exposed dummy placeholders and backside contact metallization. More specifically, the performance of operation 112 further includes the complete removal of the remainder of the dummy placeholders that were exposed during the formation of the openings, described above. The openings are thereby extended to include the space previously occupied by the remainder of the dummy placeholders that were exposed. As a result, the openings extend to the S/D epitaxy material that was previously covered by the removed dummy placeholders. The openings are then filled with conductive material to form backside contacts with the exposed surfaces of the S/D epitaxy material. Notably, those dummy placeholders that were not exposed by the formation of the openings are not removed and remain intact.

Following the performance of this portion of operation 112, backside contacts have been formed. Accordingly, following the performance of this portion of operation 112, the performance of operation 112 is complete.

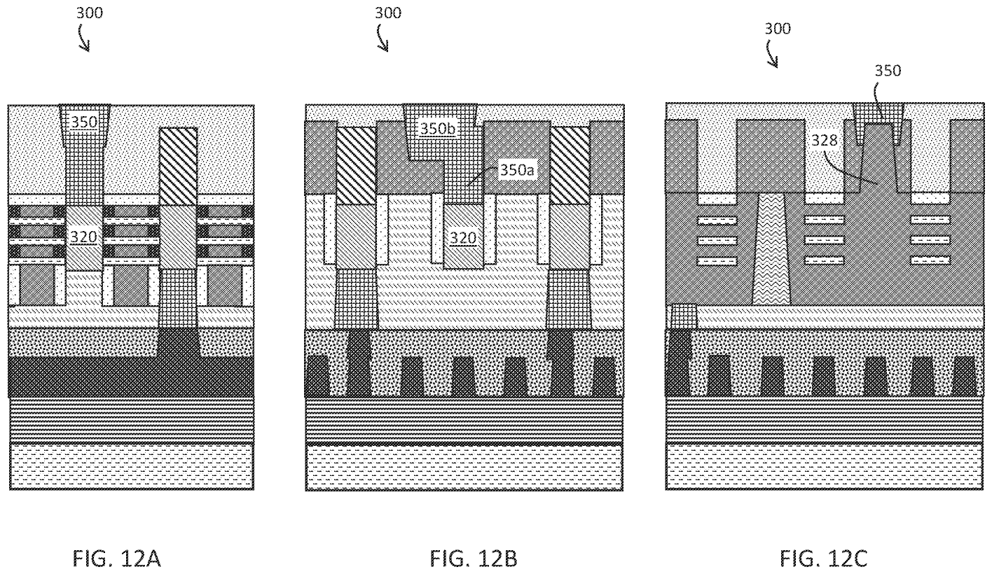

FIGS. 12A-12C depict the device 300 following the performance of operation 112. Accordingly, FIGS. 12A and 12B illustrate the results of the removal of the remainder of the dummy placeholders 316 (shown in FIGS. 11A and 11B) that were previously partially removed by the formation of the openings. The resulting openings extend to the exposed surfaces of the S/D epitaxy material 320 that were previously covered by the removed dummy placeholders. Accordingly, subsequent metallization forms backside metal contacts 350 that are in direct contact with the exposed surfaces of the S/D epitaxy material 320. FIG. 12C illustrates that, within the gate, metallization forms a backside metal contact 350 in direct contact with the gate metal extension 328.

Notably, the backside metal contact 350 shown in FIG. 12B is at least partially offset relative to the S/D epitaxy material 320 with which it is in contact due to the offset of the opening described above. In particular, a lower portion 350a of the backside metal contact 350 is in direct contact with the S/D epitaxy material 320 and is formed in the portion of the opening that was previously occupied by the dummy placeholder that was removed. Accordingly, the lower portion 350a of the backside metal contact 350 is aligned with the S/D epitaxy material 320 because the dummy placeholder was aligned with the S/D epitaxy material 320. In contrast, an upper portion 350b of the backside metal contact 350 is exposed at the top of the backside of the device 300 and is offset relative to the S/D epitaxy material 320, and therefore relative to the lower portion 350a, because it is formed in that portion of the opening that was patterned and formed offset relative to the S/D epitaxy material 320. As described in further detail below, the offset of the upper portion 350b of the backside metal contact 350 enables adequate spacing between subsequently formed power and signal lines.

Returning to FIG. 1, following the performance of operation 112, the method 100 proceeds with operation 116, wherein backside power and signal lines are formed on the device. In accordance with some embodiments of the present disclosure, the performance of operation 116 further includes the performance of a number of sub-operations.

In accordance with at least one embodiment of the present invention, the performance of operation 116 includes forming backside power and signal lines in contact with the backside metal contacts. More specifically, the performance of operation 116 includes forming a backside insulative layer above the BILD and forming patterned openings in the backside insulative layer. The performance of operation 116 further includes filling the patterned openings with conductive material to form power and signal lines that are arranged depending upon the particular application and functionality for which the device is designed.

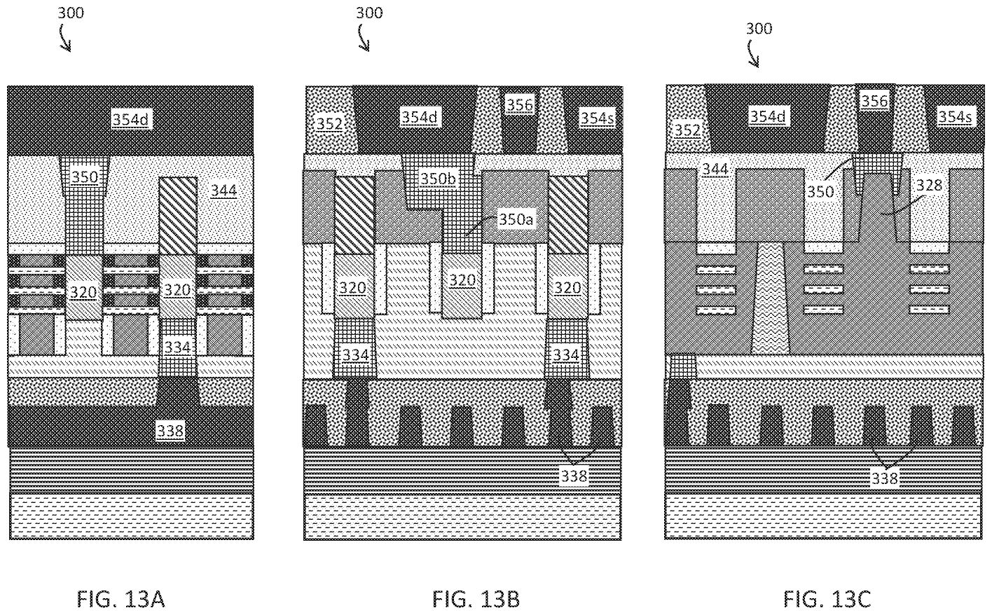

FIGS. 13A-13C depict the structure 300 following the performance of this portion of operation 116. As shown, the backside insulative layer 352 is formed on top of the BILD 344 and the backside contacts 350 formed therein. The backside insulative layer 352 is patterned and metallized to form both power lines 354d, 354s and signal lines 356 that are interconnected with the backside contacts 350. The power lines 354d supply voltage to the drain of a transistor, and the power lines 354s supply voltage to the source of a transistor. Accordingly, as shown, following the performance of this portion of operation 116, the frontside of the device 300 includes BEOL interconnects 338, specifically including signal lines, and the backside of the device 300 includes a combination of both power lines 354d, 354s and signal lines 356. Thus, the areas of conductive material 334, which can also be referred to as frontside contacts, connect the regions of S/D epitaxy material 320 of a transistor to BEOL signal lines 338. Additionally, the backside metal contacts 350 connect the regions of S/D epitaxy material 320 of a transistor to backside power lines 354d or 354s.

For illustrative purposes, in the embodiment shown in FIGS. 13A-13C, the power line 354d is formed on the top of the backside of the device 300 such that, in the view shown in FIG. 13A, which is cut perpendicular to the length of the gates 208 (shown in FIG. 2), the power line 354d covers the entirety of the top of the backside of the device 300 and is therefore in direct contact with the backside contact 350 formed therein. Additionally, in the views shown in FIGS. 13B and 13C, which are cut parallel to the length of the gates 208 (shown in FIG. 2), the power line 354d is arranged on the leftward portion of the device 300 such that, in the view shown in FIG. 13B, the power line 354d is in direct contact with the upper portion 350b of the offset backside contact 350.

The power line 354s is not visible in the view of the device 300 shown in FIG. 13A. In the views shown in FIGS. 13B and 13C, the power line 354s is arranged on the rightward portion of the device 300.

The signal line 356 is not visible in the view of the device 300 shown in FIG. 13A. In the views shown in FIGS. 13B and 13C, the signal line 356 is arranged between the power line 354d and the power line 354s such that, as shown in FIG. 13C, the signal line 356 is in direct contact with the backside metal contact 350 that is formed on the metal gate extension 328. Accordingly, the backside metal contact 350 shown in FIG. 13C and the metal gate extension 328 can be considered together as a single feature configured to connect a gate to a backside signal line 356. One portion of the feature (the metal gate extension 328) is made of the same material as the workfunction HKMG material forming the metal gates 308 and the other portion of the feature (the backside metal contact 350) is made of the same conductive material as the other metal contacts of the device.

As shown in FIGS. 13B and 13C, adequate spacing is provided between the signal line 356 and the power lines 354d, 354s to prevent interference. This spacing is enabled by the offset of the upper portion 350b of the offset backside metal contact. In other words, as illustrated by FIG. 13B, without the offset provided by the upper portion 350b, the spacing between the power lines 354d and 354s would be insufficient to ensure proper functionality of the device 300.

In accordance with at least one embodiment of the present disclosure, the leftward portion of the device 300 shown in FIGS. 13B and 13C corresponds to a pFET region and the rightward portion of the device 300 corresponds to an nFET region of the device. Accordingly, in such embodiments, power line 354d is arranged on the underside of a pFET region, power line 354s is arranged on the underside of an nFET region, and signal line 356 is arranged between the underside of the pFET region and the underside of the nFET region.

In accordance with at least one embodiment of the present disclosure, the performance of operation 116 further includes forming at least one further layer of backside interconnects. Each further layer of backside interconnects is formed in substantially the same manner as the BEOL interconnects described above with respect to FIGS. 6A-6C. The number of further layers of backside interconnects that are formed are determined by the application and function of the particular device.

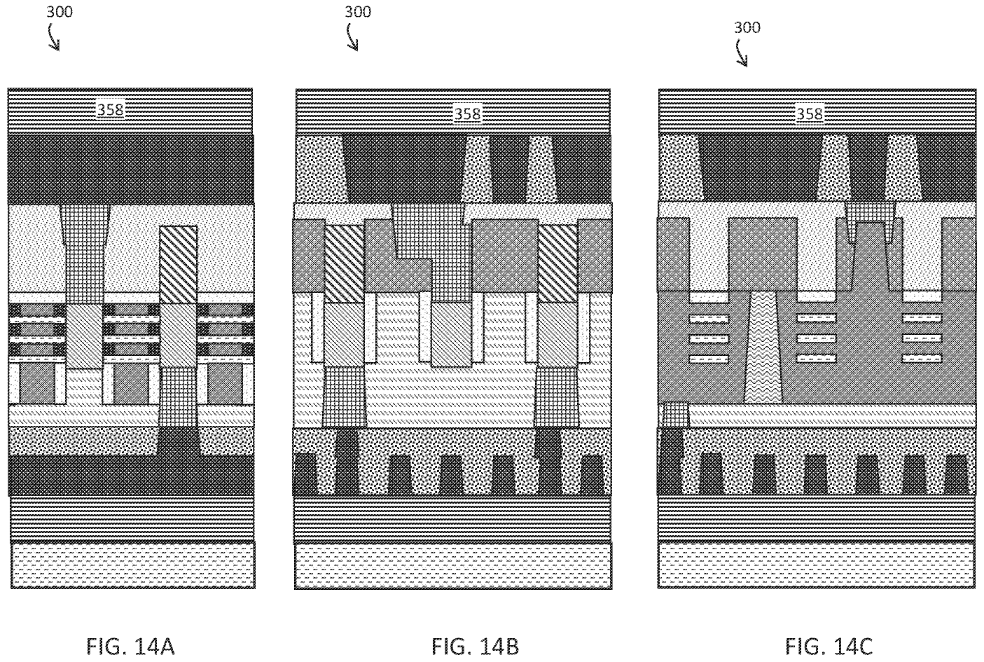

FIGS. 14A-14C depict the structure 300 following the performance of this portion of operation 116. For illustrative purposes, the further layer(s) of backside interconnects are represented in the figures simply as a single structure 358.

Returning to FIG. 1, following the performance of operation 116, the method 100 proceeds with operation 120, wherein the device is finalized. In accordance with some embodiments of the present disclosure, the performance of operation 120 further includes the performance of a number of sub-operations. In accordance with at least one embodiment of the present disclosure, the performance of operation 120 includes integrating the device into a package.

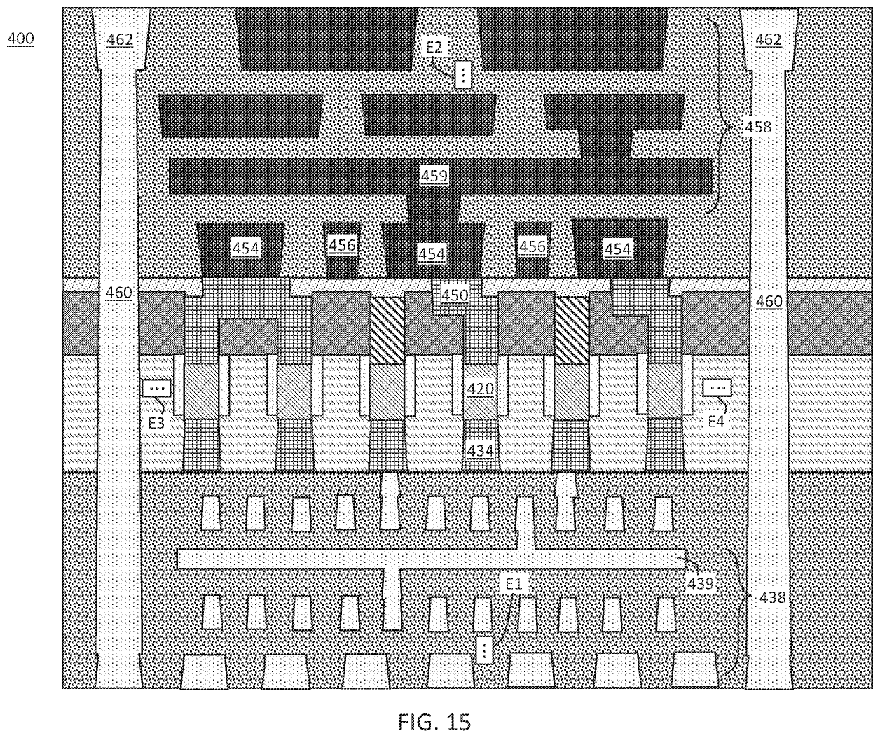

FIG. 15 depicts a device 400 following the performance of operation 120. The view of the device 400 shown in FIG. 15 is substantially similar to that shown in FIG. 14B. In other words, FIG. 15 illustrates the device 400 cut along a line that is approximately parallel to the length of gates 208 (shown in FIG. 2) and is between gates.

The device 400 is substantially similar to the device 300 shown in FIGS. 14A-14C. Accordingly, the backside of the device 400, which is arranged above the regions of S/D epitaxy material 420, provides power to sources and drains and provides signals to gates of transistors in the device 400. Additionally, the frontside of the device 400, which is arranged below the backside of the device 400, provides signals for both gates and sources and drains of transistors in the device 400.

FIG. 15 provides a zoomed-out view of the device 400 (relative to the device 300 shown in FIGS. 14B) to illustrate how the performance of the method 100 can produce a device having a plurality of backside signal lines 456 (rather than the single backside signal line 356 shown in FIGS. 13B and 13C). Accordingly, FIG. 15 also illustrates how the performance of the method 100 can produce multiple offset backside metal contacts 450 to enable sufficient spacing between power lines 454 and signal lines 456 without impacting the spacing between the regions of S/D epitaxy material 420. Thus, FIG. 15 illustrates how the performance of the method 100 produces a device 400 that enables an arrangement of both power and signal delivery lines on the backside of the wafer that is suitable for nanosheet devices with direct backside source/drain (S/D) contact and is suitable for nanosheet devices having gate contact at an aggressive pitch.

FIG. 15 further illustrates multiple layers of BEOL interconnects 438 and multiple layers of backside interconnects 458 distinctly (rather than representing multiple layers as a single structure as in FIGS. 6A-6C and 14A-14C). In accordance with at least one embodiment of the present disclosure, the BEOL interconnects 438 shown in FIG. 15 include a frontside BEOL signal rail 439 configured to serve both the source/drain and the gate of a transistor. Additionally, the backside interconnects 458 shown in FIG. 15 include a backside power rail 459 configured to provide power to the backsides of transistor sources/drains. The device 400 further includes a backside signal rail (not shown) configured to provide signals to the backsides of transistor gates.

The distinct layers of BEOL interconnects 438 and backside interconnects 458 shown in FIG. 15 are for illustrative purposes. To this end, FIG. 15 also includes ellipses E1 and E2 to indicate that alternative embodiments may include more layers than are illustrated in FIG. 15. Similarly, FIG. 15 includes ellipses E3 and E4 to indicate that alternative embodiments may include more regions of S/D epitaxy material 420, and therefore more frontside and backside metal contacts 434 and 450, respectively, than are illustrated in FIG. 15.

Notably, the device 400 also includes elongated vias 460 extending through the entirety of the final device 400, from the top surface formed by the backside of the device to the bottom surface formed by the frontside of the device, to enable transmission of signals between BEOL interconnects 438 and backside input/output (I/O) terminals 462. The elongated vias 460 can be formed during the performance of the method 100 by forming interconnected vias through each level of the device using conventional techniques.

The I/O terminals 462 and the topmost layer of backside interconnects 458 provide contact with the package with which the device 400 is integrated. Accordingly, such elongated vias 460 enable signal lines to be wired from the far BEOL interconnects 438 on the frontside of the device 400 to higher metal levels at the backside of the device 400. Thus, the elongated vias 460 provide wiring access from signal lines at the frontside of the device to metal levels at the backside of the device that contain both power and signal lines (in the form of backside power supply and I/Os to the package into which the device 400 is integrated).

In addition to embodiments described above, other embodiments having fewer operational steps, more operational steps, or different operational steps are contemplated. Also, some embodiments may perform some or all of the above operational steps in a different order. Furthermore, multiple operations may occur at the same time or as an internal part of a larger process.

In the foregoing, reference is made to various embodiments. It should be understood, however, that this disclosure is not limited to the specifically described embodiments. Instead, any combination of the described features and elements, whether related to different embodiments or not, is contemplated to implement and practice this disclosure. Many modifications and variations may be apparent to those of ordinary skill in the art without departing from the scope and spirit of the described embodiments. Furthermore, although embodiments of this disclosure may achieve advantages over other possible solutions or over the prior art, whether or not a particular advantage is achieved by a given embodiment is not limiting of this disclosure. Thus, the described aspects, features, embodiments, and advantages are merely illustrative and are not considered elements or limitations of the appended claims except where explicitly recited in a claim(s).

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. However, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to the skilled in the art. Therefore, it is intended that the following claims be interpreted as covering all such alterations and modifications as fall within the true spirit and scope of the invention.

What is claimed is:

1. A semiconductor device, comprising:
an integrated circuit chip having a frontside and a backside, the frontside including a frontside signal line configured to transmit signals to a first terminal of a transistor arranged in the integrated circuit chip, and the backside including a backside power line configured to transmit power to a second terminal of the transistor;
a contact configured to connect a gate of the transistor to a backside signal line, the backside signal line configured to transmit signals to the gate of the transistor; and
a via extending through the frontside and the backside of the integrated circuit chip, wherein the via is configured to transmit signals between a lowermost contact on the frontside of the integrated circuit chip and an uppermost contact on the backside of the integrated circuit chip.

2. The semiconductor device of claim 1, wherein the uppermost contact on the backside of the integrated circuit chip is an input-output terminal.

3. The semiconductor device of claim 1, wherein the lowermost contact on the frontside of the integrated circuit chip is a back end of line interconnect.

4. The semiconductor device of claim 1, wherein the backside of the integrated circuit chip includes a plurality of interconnect layers arranged so as to extend between the uppermost contact and the transistor.

5. The semiconductor device of claim 1, wherein the frontside of the integrated circuit chip includes a plurality of interconnect layers arranged so as to extend between the lowermost contact and the transistor.

6. A semiconductor component, comprising:
an integrated circuit chip having a frontside and a backside, the integrated circuit chip including a first FET arranged in a first FET region and a second FET arranged in a second FET region, the first FET region and the second FET region separated from one another by a space;
a first contact connecting a backside power line to a terminal of the first FET, the backside power line arranged on the backside of the integrated circuit chip;
a second contact connecting a frontside signal line to a terminal of the second FET, the frontside signal line arranged on the frontside of the integrated circuit chip;
a third contact connecting a backside signal line to a gate that connects the first FET and the second FET, the backside signal line arranged on the backside of the integrated circuit chip, wherein:
the first contact includes a first portion having a first centerline which is aligned with a centerline of the terminal of the first FET, and the first contact includes a second portion having a second centerline which is not aligned with the centerline of the terminal of the first FET.

7. The semiconductor component of claim 6, wherein the first FET is a pFET and the second FET is an nFET.

8. The semiconductor component of claim 6, wherein the first portion and the second portion of the first contact are integrally formed with one another and are made of the same material.

9. The semiconductor component of claim 6, wherein the first portion of the first contact is in direct contact with the terminal of the first FET.

10. The semiconductor component of claim 6, wherein the second portion of the first contact is in direct contact with the backside power line.

11. The semiconductor component of claim 6, wherein the first centerline of the first contact is arranged nearer to the space than is the second centerline of the first contact.

12. The semiconductor component of claim 6, further comprising a fourth contact connecting the frontside signal line to a further terminal of the first FET.

13. The semiconductor component of claim 6, wherein the backside signal line is arranged in the space.

14. The semiconductor component of claim 6, further comprising:
a gate metal extension extending into the backside of the integrated circuit chip, the gate metal extension integrally formed with the gate and formed of the same material as the gate.

15. The semiconductor component of claim 14, wherein the gate metal extension is arranged in the space.

16. The semiconductor component of claim 15, wherein:
the third contact is in direct contact with the gate metal extension and with the backside signal line, and
the third contact is made of a different material than the gate metal extension.

17. A method for forming a semiconductor device, the method comprising:
forming a frontside device on a wafer such that the frontside device includes a first FET in a first FET region, a second FET in a second FET region, a placeholder that is in direct contact with a terminal of the first FET, and a frontside contact connected to a frontside signal line;
removing the wafer from the frontside device;
creating an opening that removes a portion of the placeholder, the opening having a centerline that is offset relative to a centerline of the terminal of the first FET;
removing a remainder of the placeholder to expose the terminal of the first FET;
forming a backside device including filling the opening with contact material to form a first backside contact that is in direct contact with the terminal of the first FET, the backside device including a backside power line connected to the first backside contact and a backside signal line connected to a second backside contact such that the backside signal line is arranged between the first FET region and the second FET region.

18. The method of claim 17, wherein the opening is created such that the centerline of the opening is farther from the second FET region than is the centerline of the terminal.

19. The method of claim 17, wherein forming the frontside device further includes forming a gate connecting the first FET and the second FET, the gate including a gate metal extension that extends toward the backside device and is made of the same material as the gate.

20. The method of claim 19, wherein forming the backside device further includes forming the second backside contact in direct contact with the metal gate extension, the second backside contact is made of a different material than the gate.
